(19) United States
(12) Patent Application Publication
(10) Pub. No.: US 2006/0024959 A1
(43) Pub. Date: Feb. 2, 2006

(54) Thin tungsten silicide layer deposition and gate metal integration

(75) Inventors: Ming Li, Cupertino, CA (US); Shulin Wang, Campbell, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/179,274

(22) Filed: Jul. 12, 2005

Related U.S. Application Data
(60) Provisional application No. 60/592,585, filed on Jul. 30, 2004.

(51) Int. Cl. H01L 21/8238; H01L 21/4763

(52) U.S. Cl. 438/648; 438/199

(57) ABSTRACT

A method for depositing layers of a gate electrode is provided. The method includes depositing a doped polysilicon layer, a thin tungsten silicide layer, and a metal layer. In one aspect, the doped polysilicon layer and the thin tungsten silicide layer are deposited within an integrated processing system. In a further aspect, depositing the thin tungsten silicide layer includes exposing a polysilicon layer to a silicon source, depositing a tungsten silicide layer, and exposing the tungsten suicide layer to a silicon source.

### CROSS-REFERENCE TO RELATED APPLICATIONS

This application claims benefit of U.S. Provisional Patent Application Ser. No. 60/592,585, filed Jul. 30, 2004, which is herein incorporated by reference.

### BACKGROUND OF THE INVENTION

1. Field of the Invention

Embodiments of the present invention generally relate to methods of depositing layers of a gate electrode.

2. Description of the Related Art

Integrated circuits are composed of many, e.g., millions, of devices such as transistors, capacitors, and resistors. Transistors, such as field effect transistors, typically include a source, a drain, and a gate stack. The gate stack typically includes a substrate, such as a silicon substrate, a gate dielectric, such as silicon dioxide (SiO₂) on the substrate, and a gate electrode on the gate dielectric.

Materials that have been used for gate electrodes include metals, such as aluminum (Al), and polysilicon. Doped polysilicon has become a preferred material for gate electrodes, as doped polysilicon has a lower threshold voltage than aluminum. The threshold voltage is the amount of voltage that is required for formation of the channel under the gate that connects the source and drain of a transistor. A lower threshold voltage is preferred as it reduces the amount of power required by the transistor and increases the speed of the transistor.

Gate electrodes including a stack of a tungsten (W) or tungsten nitride (WN)/tungsten layer on a polysilicon layer have also been developed. Gate electrodes including a stack of a tungsten or tungsten nitride/tungsten layer on a polysilicon layer can be formed such that the gate electrodes have a low resistance, which is becoming increasingly important with the development of 90 nm and smaller transistors. However, it has been found that the treatment of such gate electrodes with subsequent processing steps, such as annealing, can result in undesirable interactions between the tungsten or tungsten nitride layer and the polysilicon layer. For example, a non-uniform silicon nitride (SiN) or tungsten silicide (WSiₓ) layer may be formed between the polysilicon and tungsten or tungsten nitride layers when the layers are annealed. Reactions between the polysilicon and tungsten or tungsten nitride layers can also affect the resistance of the gate electrode and device reliability.

Thus, there remains a need for gate electrodes having a low resistance and stable chemical and electrical properties.

### SUMMARY OF THE INVENTION

Embodiments of the present invention generally provide a method of depositing layers of a gate electrode on a substrate, comprising depositing a polysilicon layer on a substrate, depositing a tungsten silicide layer having a thickness of between about 20 Å and about 80 Å on the polysilicon layer, and depositing a metal layer on the tungsten silicide layer to form the layers of the gate electrode. In one embodiment, the polysilicon layer is a doped polysilicon layer, and a polysilicon-rich layer is deposited on the doped polysilicon layer.

Embodiments of the invention also provide a method of depositing layers of a gate electrode on a substrate, comprising depositing a polysilicon layer on a substrate, depositing a tungsten silicide layer having a thickness of between about 20 Å and about 80 Å on the polysilicon layer, wherein depositing the tungsten silicide layer comprises exposing the polysilicon layer to silane, reacting a gas mixture comprising dichlorosilane and tungsten hexafluoride to deposit the tungsten silicide layer, and exposing the tungsten silicide layer to silane, and then depositing a metal layer on the tungsten silicide layer to form the layers of the gate electrode. In one embodiment, exposing the polysilicon layer to silane comprises depositing a thin silicon layer on the polysilcion layer, and exposing the tungsten silicide layer to silane comprises depositing a thin silicon layer on the tungsten silicide layer.

In another embodiment, a method of processing a substrate comprising depositing a polysilicon layer on the substrate in a first chamber of an integrated processing system and depositing a tungsten silicide layer having a thickness of between about 20 Å and about 80 Å on the polysilicon layer in a second chamber of the integrated processing system, wherein the substrate is not exposed to an atmosphere external to the integrated processing system after depositing the polysilicon layer and before depositing the tungsten silicide layer, is provided.

In a further embodiment, a method of depositing layers of a gate electrode on a substrate comprising depositing a polysilicon layer on the substrate, depositing a layer having a thickness of between about 20 Å and about 80 Å on the polysilicon layer under conditions sufficient to provide a sheet resistance of the layer of about 2500 Ω/cm² or greater, and depositing a metal layer on the layer is provided.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a graph showing the phosphorus concentration profile of a doped polysilicon layer and a polysilicon-rich layer deposited thereon according to an embodiment of the invention.

FIG. 2 is a top schematic view of an integrated processing system.

FIG. 3 is a cross-sectional view of a structure that includes multiple layers that comprise a gate electrode according to an embodiment.

FIG. 4 is a flow chart depicting one embodiment of the invention.

FIG. 5 is a cross-sectional view of a device that includes a gate electrode formed according to one embodiment.

FIG. 6 is a graph showing the oxygen concentration at the interface between polysilicon layers and tungsten silicide layers deposited according to different embodiments.

### DETAILED DESCRIPTION

Embodiments of the invention relate to a method for depositing layers of a gate electrode on a substrate. Embodiments of the invention provide a method of depositing a thin layer between a polysilicon layer and a metal layer wherein the thin layer has a sheet resistance of about 2500 Ω/cm² or greater. In one embodiment, the layers include a polysilicon layer, a tungsten silicide (WSiₓ) layer, and a metal layer. The layers provide a gate electrode stack having a desirable sheet resistance and good adhesion between the layers of the stack. The tungsten silicide layer is a thin adhesion or glue layer that enhances the adhesion between the metal layer and the polysilicon layer and prevents undesirable reactions between the metal layer and the polysilicon layer. Since the tungsten silicide layer is very thin, i.e., about 20 Å to about 80 Å thick, the tungsten silicide layer does not significantly increase the resistance of the gate electrode stack. Tungsten silicide layers having a sheet resistance of at least about 2500 Ω/cm² as measured on an undoped silicon substrate were obtained according to embodiments of the invention.

In one embodiment, a polysilicon layer is deposited on a substrate. The substrate may be a silicon or silicon-containing substrate. As defined herein, a silicon substrate includes single layer silicon substrates, such as silicon wafers, or structures that include a silicon layer on top of one or more other layers. Typically, the substrate has a thin gate oxide layer formed thereon. The gate oxide layer may be a silicon oxide layer formed by exposing the substrate to an atmosphere comprising oxygen to oxidize the top surface of the substrate.

The polysilicon layer may be about 500 Å to about 2000 Å thick. In one aspect, the polysilicon layer is a doped polysilicon layer, such as a phosphorus doped polysilicon layer. The polysilicon layer may be deposited by reacting a gas mixture comprising a silicon source, such as silane (SiH₄) or disilane (Si₂H₆), and a dopant source, such as phosphine (PH₃), in a thermal chemical vapor deposition process. The thermal chemical vapor deposition process may be performed in a POLYgen™ chamber of a Polycide Centura® system. The gas mixture may further comprise a carrier gas, such as nitrogen or an inert gas, such as argon or helium. Exemplary deposition conditions for the polysilicon layer include a silicon source flow rate of between about 30 sccm and about 200 sccm into a processing chamber, a chamber pressure of between about 50 Torr and about 300 Torr, and a substrate support temperature of between about 570° C. and about 750° C. Typically, the temperature of the substrate is about 30° C. less than the temperature of the substrate support. It is to be noted that the processing conditions provided above and throughout the application are processing conditions for a 300 mm substrate, and that the processing conditions may be adjusted accordingly for other sizes of substrates.

In an alternative embodiment, a doped polysilicon layer may be formed by depositing an undoped polysilicon layer and then exposing the undoped polysilicon layer to a dopant source.

After the doped polysilicon layer is deposited, a polysilicon-rich layer may be deposited on the doped polysilicon layer. As defined herein, a polysilicon-rich layer is a polysilicon layer containing a lower concentration of the dopant of the doped polysilicon layer or an undoped polysilicon layer. For example, the doped polysilicon layer may have a dopant concentration of about 1×10²⁰ to about 1×10²¹ atoms/cm³ and the polysilicon-rich layer may have a dopant concentration of about 1×10¹⁹ atoms/cm³ at its upper surface such that the polysilicon-rich layer has a lower dopant concentration than the polysilicon layer. The polysilicon-rich layer may be deposited in the same chamber used to deposit the doped polysilicon chamber such that the deposition of the doped polysilicon layer and the polysilicon-rich layer are performed in situ, i.e., in the same chamber without exposing the substrate to an atmosphere external to the chamber between the deposition of the two layers. The polysilicon-rich layer may be deposited by terminating the flow of the dopant source into the chamber and continuing the flow of the silicon source in the chamber. In another embodiment, the flows of the dopant source and the silicon source into the chamber are terminated and the chamber is purged, such as with a flow of a carrier gas, before the flow of the silicon source into the chamber is resumed to deposit the polysilicon-rich layer.

Alternatively, the polysilicon-rich layer may be deposited in a different chamber than the chamber used to deposit the polysilicon layer. The chamber used to deposit the polysilicon layer and the chamber used to deposit the polysilicon-rich layer may be part of an integrated processing system such that both layers may be deposited without breaking vacuum and exposing the substrate to an atmosphere external to the integrated processing system between the deposition of the two layers.

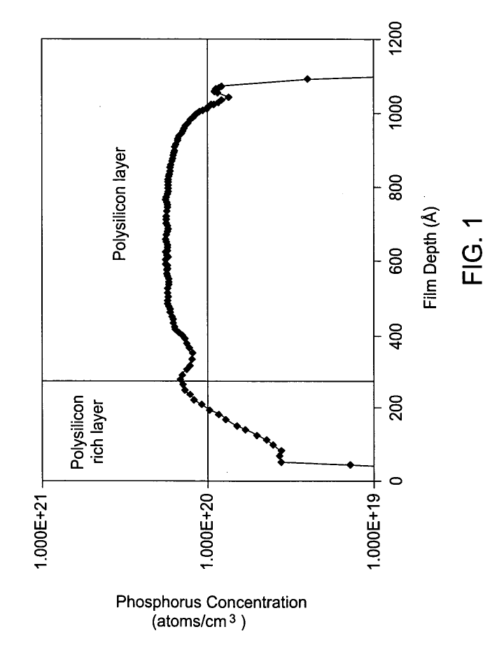

The polysilicon-rich layer may have a concentration gradient of the dopant, with the concentration of the dopant decreasing during the deposition of the polysilicon-rich layer as the remaining dopant source is removed from the chamber, as shown in FIG. 1. FIG. 1 shows the phosphorus concentration profile of a doped polysilicon layer having a polysilicon-rich layer deposited thereon. The surface of the polysilicon-rich layer has a phosphorus concentration of about 3×10¹⁹ atoms/cm³. The phosphorus concentration of the polysilicon-rich layer increases with the depth of the polysilicon-rich layer until it is substantially the same as the phosphorus concentration of the doped polysilicon layer (about 2×10²⁰ atoms/cm³).

It is believed that the deposition of the polysilicon-rich layer enhances the nucleation of the subsequently deposited tungsten silicide layer, as it has been observed that dopant sources such as phosphine for the doped polysilicon layer can impair the silicon contribution from the silicon source used to deposit the tungsten silicide layer.

After the doped polysilicon layer and the polysilicon-rich layer are deposited, a tungsten silicide layer is deposited thereon. The tungsten suicide layer may be deposited by reacting a gas mixture comprising a silicon source, such as dichlorosilane (SiH₂Cl₂) or silane (SiH₄), and a tungsten source, such as tungsten hexafluoride (WF₆) in a thermal chemical vapor deposition process. The gas mixture may further comprise a carrier gas, such as nitrogen or an inert gas. Exemplary deposition conditions for the tungsten silicide layer include a silicon source flow rate of between about 30 sccm and about 100 sccm into a deposition chamber, a tungsten source flow rate of between about 1 sccm and about 3 sccm into the deposition chamber, a chamber pressure of between about 0.8 Torr and about 2 Torr, and a substrate support temperature of between about 400° C. and about 650° C. The substrate support temperature may vary according to the silicon source used. For example, a substrate support temperature of between about 500° C. and 650° C. is preferred when dichlorosilane is used as the silicon source, and a substrate support temperature of between about 400° C. and about 500° C. is preferred when silane is used as the silicon source. The tungsten silicide layer may have a thickness of between about 20 Å and about 80 Å and a silicon to tungsten ratio of between about 2.1:1 and about 3.0:1. The silicon to tungsten ratio is tunable, such as by adjusting the ratio of the silicon source and tungsten source flow rates.

In a preferred embodiment, depositing the tungsten silicide layer comprises exposing the polysilicon layer, i.e., either a doped polysilicon layer or a polysilicon-rich layer on top of a doped polysilicon layer as described above, to a silicon source, such as silane, before reacting the gas mixture comprising a silicon source and a tungsten source to deposit the tungsten silicide layer on the polysilicon layer. The polysilicon layer may be exposed to the silicon source in the same chamber used to deposit the tungsten silicide layer. A carrier gas may be introduced into the chamber before the silicon source. The silicon source may be introduced into the chamber at a flow rate of between about 300 sccm and about 1200 sccm, such as about 700 sccm, with a chamber pressure of between about 5 Torr and about 10 Torr and a substrate support member in the chamber heated to a temperature of between about 400° C. and about 650° C., such as about 550° C. The silicon source may be flowed into the chamber for a period of time sufficient to deposit a thin layer of silicon, such as several atomic layers of silicon, e.g., 1-2 atomic layers having a thickness between about 5 Å and about 10 Å on the polysilicon layer. For example, the silicon source may be flowed into the chamber at a rate of about 300 sccm to about 1200 sccm for about 20 seconds to about 50 seconds. It is believed the deposition of a thin silicon layer enhances the nucleation of the tungsten silicide layer and contributes to the formation of a tungsten silicide layer that has a silicon/tungsten ratio of 2 or greater. A 50 Å tungsten silicide layer deposited on a polysilicon layer according to an embodiment of the invention had a silicon/tungsten ratio of about 2.4:1, as measured by X-ray photoelectron spectroscopy (XPS).

A tungsten silicide layer having a silicon/tungsten ratio of 2 or greater is desired as it has been observed that tungsten silicide layers having lower silicon/tungsten ratios can provide excess tungsten radicals that react with the underlying polysilicon layer during subsequent substrate processing steps, such as annealing, and form an interface having physical and resistivity non-uniformities between the polysilicon layer and the tungsten silicide layer. A tungsten silicide layer having a silicon/tungsten ratio of 2 or greater is also desired as it has been found that tungsten silicide layers having a lower silicon/tungsten ratio have a tendency to be delaminated.

After exposing the polysilicon layer to the silicon source to deposit a thin silicon layer in the embodiment described above, dichlorosilane is introduced into the chamber. A stable flow rate of the dichlorosilane is established in the chamber. For example, a dichlorosilane flow rate of between about 30 sccm and about 100 sccm, such as about 60 sccm, and a chamber pressure of about 1 to about 1.2 Torr may be used. Then, tungsten hexafluoride is introduced into the chamber, such as with a flow rate of between about 1 sccm and about 3 sccm, such as about 2 sccm and a chamber pressure of about 0.8 Torr to about 2 Torr, such as about 1 to about 1.2 Torr. The dichlorosilane and tungsten hexafluoride are reacted within the chamber to deposit a tungsten silicide layer. The substrate support member in the chamber may be heated to a temperature of between about 400° C. and about 650° C., such as about 550° C., during the deposition of the tungsten silicide layer. As discussed above, the temperature may be varied depending on the source gases used. Optionally, a flow of dichlorosilane is maintained with a flow of carrier gas to purge the chamber after the deposition of the tungsten silicide layer.

After the deposition of the tungsten silicide layer, the tungsten silicide layer may be exposed to a flow of a silicon source, such as silane. A carrier gas may also be used. The silane may be flowed into the chamber at a rate between about 100 sccm and about 700 sccm at a substrate support member temperature of between about 500° C. and about 600° C. and a chamber pressure of between about 0.8 Torr to about 2 Torr, such as about 1 to about 1.2 Torr. Exposing the tungsten silicide layer to the silane flow enables the removal of unwanted fluorine atoms that may be associated with the tungsten silicide layer as a residue from a fluorine-containing precursor, such as WF₆, used to deposit the layer. The silane decomposes and combines with the fluorine atoms to form HF and SiF₄ which can be pumped out of the chamber. Exposing the tungsten silicide layer to the silane may also form a silicon-rich cap on the tungsten silicide which can be oxidized to form a silicon oxide cap that protects the underlying layers.

In another embodiment, the exposure of the polysilicon layer to a silicon source, deposition of the tungsten silicide layer, and exposure of the tungsten silicide layer to a silicon source may be performed in different chambers within an integrated processing system such that the substrate is not exposed to an atmosphere external to the integrated processing system from the exposure of the polysilicon layer to a silicon source through the exposure of the tungsten silicide layer to a silicon source.

Optionally, after the tungsten silicide layer is exposed to the silane, a flow of ammonia (NH₃) may be introduced into the chamber to form tungsten-nitrogen bonds on the surface of the tungsten silicide layer and enhance the deposition of a tungsten nitride layer thereon.

After the deposition of the tungsten suicide according to any of the embodiments described herein, a metal layer is deposited on the tungsten silicide layer. The metal layer may be a tungsten layer, tungsten nitride layer, or a combination thereof, such as a tungsten nitride layer followed by a tungsten layer. The tungsten and tungsten nitride layers may be deposited by CVD, physical vapor deposition (PVD), or atomic layer deposition (ALD), for example. Exemplary processing conditions for depositing the tungsten and tungsten nitride layers are disclosed in commonly assigned U.S. patent application Ser. No. 10/084,767, entitled “Cyclical Deposition of Tungsten Nitride for Metal Oxide Gate Electrode,” filed on Feb. 26, 2002, which is incorporated herein by reference to the extent not inconsistent with the disclosure and claimed aspects of the invention described herein.

Integrated Processing Sequence

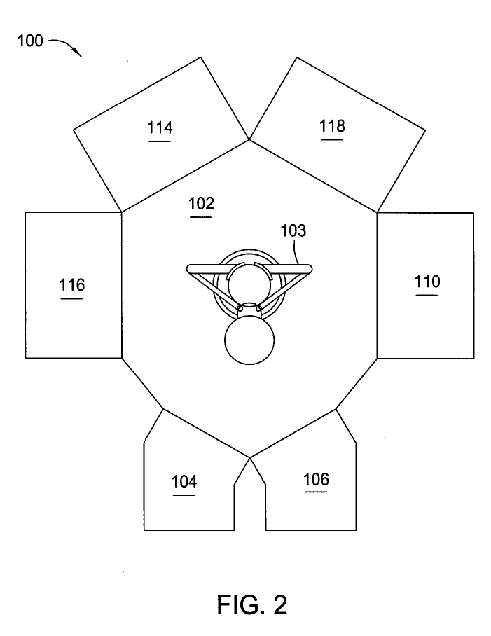

In one embodiment, an integrated method of depositing layers of a gate electrode, the layers comprising a polysilicon layer and a tungsten silicide layer having a thickness of between about 20 Å and about 80 Å, on a substrate within an integrated processing system is provided. An example of an integrated processing system 100 that may be used is the Polycide Centura® system, available from Applied Materials, Inc. of Santa Clara, Calif., which is shown schematically in FIG. 2. The integrated processing system 100 may include a central transfer chamber 102, transfer robot 103, load locks 104, 106, and processing chambers 110, 114, 116, and 118. Processing chambers 110, 114, 116, and 118 are thermal chemical vapor deposition chambers. In one embodiment, processing chambers 110 and 116 are POLYgen™ chambers, and processing chambers 114 and 118 are DCS (dichlorosilane) xZ 300 chambers, both of which are available from Applied Materials, Inc. POLYgen™ chambers are low pressure chemical vapor deposition (LPCVD) chambers that may be used to deposit the doped and polysilicon-rich layers of embodiments of the invention. DCS xZ 300 chambers are chemical vapor deposition chambers that may be used to deposit tungsten silicide layers according to embodiments of the invention.

In an alternative embodiment (not shown), a Polycide Centura® system having only two processing chambers, wherein one processing chamber is a POLYgen™ chamber and the other processing chamber is a DCS xZ 300 chamber, may be used.

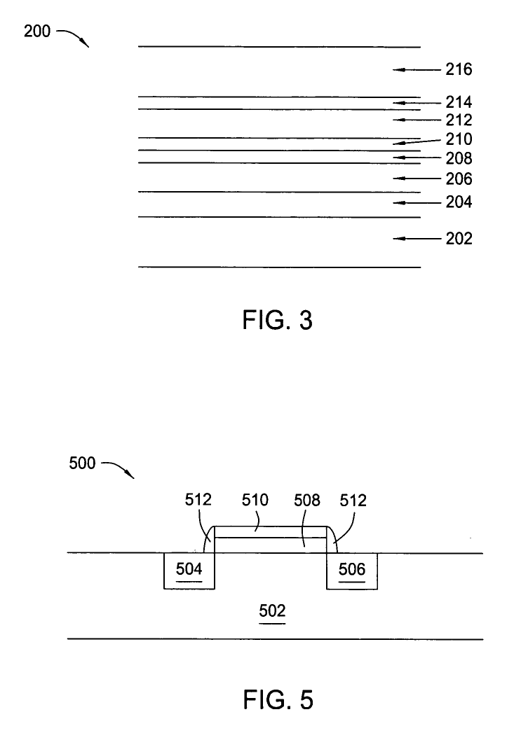

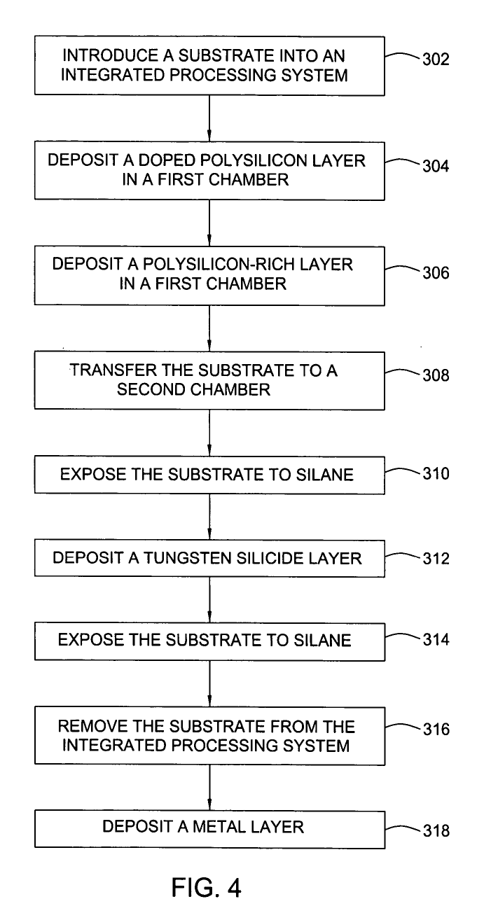

An embodiment of a method of depositing layers of a gate electrode on a substrate, wherein the method includes an integrated processing sequence will be described below with respect to FIGS. 2-4. FIG. 3 is a cross-sectional view of a structure 200 that includes layers of a gate electrode. FIG. 4 is a flow chart summarizing a processing sequence of the embodiment.

In the embodiment shown in FIG. 3, a substrate 202 is introduced into the integrated processing system 100, as shown in step 302 (FIG. 4). The substrate 202 includes a gate oxide layer 204 thereon. The substrate 202 is introduced into the integrated processing system 100 through the load lock 104 or 106. The substrate 202 is transferred to processing chamber 110 by the transfer robot 103. A doped polysilicon layer 206 is deposited on the gate oxide layer 204 in processing chamber 110, as shown in step 304. A polysilicon-rich layer 208 is then deposited on the doped polysilicon layer 206 in the processing chamber 110, as shown in step 306. The substrate 202 is transferred to processing chamber 118 by the transfer robot 103, as shown in step 308. The substrate 202 and the layers thereon are exposed to silane in processing chamber 118, as shown in step 310. The substrate 202 and the layers thereon may be exposed to the silane for a period of time sufficient to deposit a thin layer of silicon 210 thereon. A tungsten silicide layer 212 is then deposited in processing chamber 118, as shown in step 312. Next, the substrate 202 and the layers thereon are exposed to silane in processing chamber 114, as shown in step 314. The substrate 202 and the layers thereon may be exposed to the silane for a period of time sufficient to form a silicon-rich cap 214. The substrate 202 is then removed from the integrated processing system 100, as shown in step 316. A metal layer 216 is deposited on top of the layers deposited on the substrate, as shown in step 318. The metal layer may be a tungsten layer, tungsten nitride layer, or a combination thereof.

While in some embodiments of the invention, a polysilicon layer is deposited on a substrate and then a tungsten silicide layer is deposited on the polysilicon layer without exposing the substrate to atmosphere, in other embodiments, the substrate may be exposed to atmosphere after the deposition of the polysilicon layer and before the deposition of the tungsten silicide layer. In such embodiments, the substrate may be cleaned by exposing the substrate to hydrofluoric acid (HF), e.g., by rinsing the substrate with HF, after the deposition of the polysilicon layer and before the deposition of the tungsten silicide layer.

An example of a semiconductor device that includes layers of a gate electrode according to an embodiment of the invention is shown in FIG. 5. FIG. 5 depicts a NMOS transistor 500 comprising a substrate 502 having source 504 and drain 506 regions. The substrate has a gate oxide layer 508 formed thereon between the source 504 and drain 506 regions. Gate electrode 510 includes gate electrode layers (not shown) formed according to any of the embodiments of the invention. Spacers 512 surround the gate oxide layer 508 and the gate electrode 510.

Embodiments of the invention are further described by the following example which is not intended to limit the scope of the claimed invention.

### EXAMPLE

A 300 mm substrate having an oxide layer formed thereon was introduced into a Polycide Centura® system comprising a POLYgen™ chamber and a DCS xZ 300 chamber. A doped polysilicon layer was deposited on the substrate in a POLYgen™ chamber using a thermal chemical vapor deposition process from a gas mixture comprising silane and 1% phosphine diluted with hydrogen. The doped polysilicon layer was deposited at a pressure of 150 Torr with a phosphine flow rate of 99 sccm and a disilane flow rate of 50 sccm for about 55 seconds at a substrate support temperature of 600° C. and a substrate temperature of approximately 558° C. Nitrogen was flowed into the chamber prior to the deposition and was continued during and after the deposition. An undoped polysilicon layer was then deposited on the doped polysilicon layer using a disilane flow rate of 80 sccm for about 25 seconds, a pressure of 150 Torr, and a substrate support temperature of 600° C. and a substrate temperature of approximately 558° C. The substrate was then transferred to a DCS xZ 300 chamber. Argon was introduced through a dichlorosilane source port in the chamber at 1000 sccm and was also introduced through a tungsten hexafluoride source port in the chamber at 1000 sccm and maintained through the deposition of the tungsten silicide layer. The substrate was then exposed to silane for 35 seconds at a flow rate of 300 sccm. Dichlorosilane was then introduced into the chamber at a flow rate of 60 sccm for 10 seconds before tungsten hexafluoride was introduced into the chamber at a flow rate of 2 sccm and the flow of dichlorosilane was maintained with the flow of tungsten hexafluoride for 20 seconds to deposit a 50 Å tungsten silicide layer. The tungsten silicide layer was deposited at a substrate support temperature of 550° C. and a substrate temperature of approximately 443° C. at a pressure of 1.2 Torr. The flow of tungsten hexafluoride was terminated, and the flow of dichlorosilane was maintained for 10 seconds. The substrate was then exposed to silane at a flow rate of 100 sccm for 10 seconds at a substrate support temperature of 550° C. and a substrate temperature of approximately 443° C. at a pressure of 2 Torr.

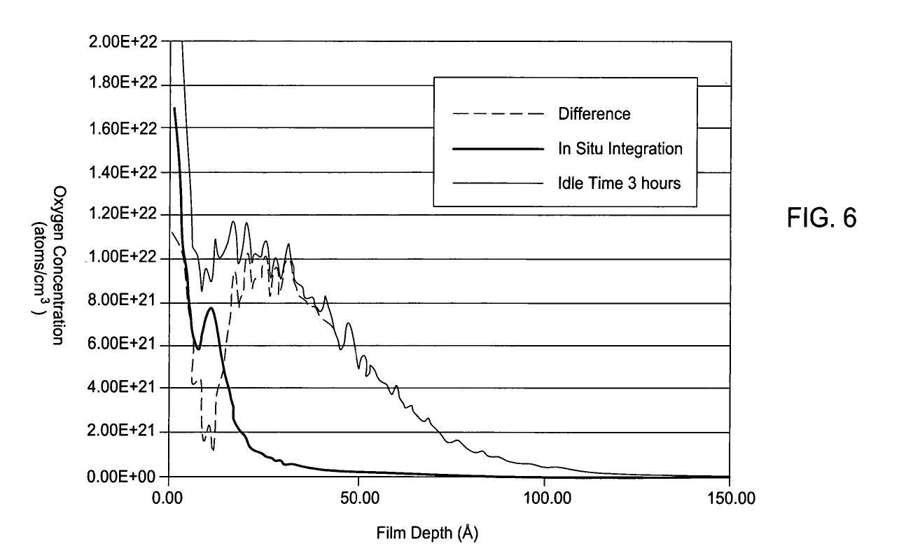

By depositing the polysilicon layer and the tungsten silicide layer without removing the substrate from the integrated processing system between the deposition of the polysilicon layer and the tungsten suicide layer, oxidation of the interface between the polysilicon layer and the tungsten silicide layer from oxygen exposure is minimized. While the substrate is transferred between chambers through the transfer chamber of the integrated processing system between the deposition of the polysilicon layer and the tungsten silicide layer, the transfer chamber is typically maintained with a nitrogen atmosphere such that exposure of the substrate to oxygen is minimized while the substrate is within the integrated processing system. The transfer chamber may have a pressure of about 2.5 to about 5 Torr, such as about 3 Torr. As shown in FIG. 6, a polysilicon layer and a tungsten silicide layer can be deposited within an integrated processing system (in situ integration line in FIG. 6) such that the oxygen concentration at the interface between the polysilicon layer and the tungsten suicide layer is less than the oxygen concentration at the interface between a polysilicon layer and a tungsten silicide layer, wherein the polysilicon layer is deposited in a first processing chamber and the tungsten silicide layer is exposed to the external atmosphere and deposited three hours later in a second processing chamber (idle time 3 hours line in FIG. 6). While the oxygen concentration at the interface between a polysilicon layer and a tungsten silicide layer of a substrate exposed to the external atmosphere can be reduced by rinsing the substrate with hydrofluoric acid (HF), it is preferred to deposit the polysilicon layer and the tungsten silicide layer within an integrated processing system.

While the foregoing is directed to embodiments of the present invention, other and further embodiments of the invention may be devised without departing from the basic scope thereof, and the scope thereof is determined by the claims that follow.

What is claimed is:

1. A method of depositing layers of a gate electrode on a substrate, comprising;
depositing a polysilicon layer on the substrate;
depositing a tungsten silicide layer having a thickness of between about 20 Å and about 80 Å on the polysilicon layer; and
depositing a metal layer on the tungsten silicide layer.

2. The method of claim 1, wherein depositing the tungsten silicide layer comprises reacting a gas mixture comprising a silicon source and a tungsten source in a thermal chemical vapor deposition process.

3. The method of claim 2, wherein the silicon source is dichlorosilane and the tungsten source is tungsten hexafluoride.

4. The method of claim 2, wherein the silicon source is silane and the tungsten source is tungsten hexafluoride.

5. The method of claim 2, wherein depositing the tungsten silicide layer further comprises depositing a silicon layer having a thickness between about 5 Å and about 10 Å on the polysilicon layer before reacting the gas mixture.

6. The method of claim 5, further comprising exposing the deposited tungsten silicide layer to silane.

7. The method of claim 1, wherein the polysilicon layer is doped, and a polysilicon-rich layer comprising a lower concentration of dopant than the polysilicon layer is deposited on the polysilicon layer before the tungsten silicide layer is deposited.

8. The method of claim 1, wherein the tungsten suicide layer has a silicon to tungsten ratio of between about 2.1:1 and about 3.0:1.

9. The method of claim 1, wherein the metal layer is a tungsten layer, tungsten nitride layer, or a combination thereof.

10. The method of claim 1, further comprising cleaning the substrate after depositing the polysilicon layer and before depositing the tungsten silicide layer, wherein cleaning the substrate comprises exposing the substrate to hydrofluoric acid.

11. A method of depositing layers of a gate electrode on a substrate, comprising;
depositing a polysilicon layer on the substrate;
depositing a tungsten silicide layer having a thickness of between about 20 Å and about 80 Å on the polysilicon layer, wherein depositing the tungsten silicide layer comprises:
exposing the polysilicon layer to silane;
reacting a gas mixture comprising dichlorosilane and tungsten hexafluoride to deposit the tungsten silicide layer; and
exposing the tungsten silicide layer to silane; and
depositing a metal layer on the tungsten silicide layer.

12. The method of claim 11, wherein the tungsten silicide layer is deposited in a substrate processing chamber, and exposing the tungsten silicide layer to silane comprises introducing the silane into the substrate processing chamber at a flow rate of between about 100 sccm and about 700 sccm at a pressure between about 0.8 Torr and about 2 Torr.

13. The method of claim 11, wherein exposing the polysilicon layer to silane comprises introducing the silane into a substrate processing chamber at a flow rate of between about 300 sccm and about 1200 sccm at a pressure between about 5 Torr and about 10 Torr.

14. The method of claim 11, further comprising depositing a polysilicon-rich layer on the doped polysilicon layer before the depositing a tungsten suicide layer, wherein the polysilicon layer is doped, and the polysilicon-rich layer has a lower dopant concentration than the doped polysilicon layer.

15. The method of claim 11, wherein the substrate is supported on a substrate support member heated to a temperature between about 400° C. and about 650° C. during the depositing the tungsten silicide layer.

16. The method of claim 11, further comprising cleaning the substrate after depositing the polysilicon layer and before depositing the tungsten silicide layer, wherein cleaning the substrate comprises exposing the substrate to hydrofluoric acid.

17. A method of processing a substrate, comprising;
depositing a polysilicon layer on the substrate in a first chamber of an integrated processing system; and
depositing a tungsten silicide layer having a thickness of between about 20 Å and about 80 Å on the polysilicon layer in a second chamber of the integrated processing system, wherein the substrate is not exposed to an atmosphere external to the integrated processing system after the depositing a polysilicon layer and before the depositing a tungsten silicide layer.

18. The method of claim 17, further comprising depositing a metal layer on the tungsten silicide layer, wherein the polysilicon layer, tungsten silicide layer, and metal layer form layers of a gate electrode on the substrate.

19. The method of claim 18, wherein the metal layer is a tungsten layer, tungsten nitride layer, or combination thereof.

20. The method of claim 17, wherein depositing the tungsten silicide layer comprises:
exposing the polysilicon layer to silane;
reacting a gas mixture comprising dichlorosilane or silane and tungsten hexafluoride to deposit the tungsten silicide layer; and
exposing the tungsten silicide layer to silane.
